(19) United States
(12) Patent Application Publication
(10) Pub. No.: US 2026/0020160 A1
(43) Pub. Date: Jan. 15, 2026

(54) COMPONENT BUILT-IN WIRING BOARD AND METHOD FOR MANUFACTURING COMPONENT BUILT-IN WIRING BOARD

(71) Applicant: IBIDEN CO., LTD., Ogaki (JP)

(72) Inventors: Yuichi NAKAMURA, Ogaki (JP); Kazuki KAJIHARA, Ogaki (JP); Yukinobu MIKADO, Ogaki (JP); Shinichi FUKUTA, Ogaki (JP)

(73) Assignee: IBIDEN CO., LTD., Ogaki (JP)

(21) Appl. No.: 19/262,594

(22) Filed: Jul. 8, 2025

(30) Foreign Application Priority Data
Jul. 9, 2024 (JP) 2024-110405

(51) Int. Cl. H05K 1/18; H05K 1/11

(52) U.S. Cl. CPC H05K 1/185; H05K 1/115; H05K 2201/09545

(57) ABSTRACT

A component built-in wiring board includes a core substrate, a connecting component positioned in opening of the substrate and including electronic components, a first build-up part formed on a first surface side of the substrate, a second build-up part formed on a second surface side of the substrate, and filling resin part filling space formed between the substrate and connecting component in the opening of the substrate. The connecting component includes molding resin part positioning the electronic components spaced apart from each other, and penetrating conductors formed in the molding resin part, and the electronic components include a first component having terminals on the first surface side of the substrate and a second component having terminals on the second surface side of the substrate such that the penetrating conductors are formed on the second surface side and connected to the terminals of the second component on the second surface side.

### CROSS-REFERENCE TO RELATED APPLICATIONS

The present application is based upon and claims the benefit of priority to Japanese Patent Application No. 2024-110405, filed Jul. 9, 2024, the entire contents of which are incorporated herein by reference.

### BACKGROUND OF THE INVENTION

### Field of the Invention

The present invention relates to a component built-in wiring board and a method for manufacturing the component built-in wiring board.

### Description of Background Art

Japanese Patent Application Laid-Open Publication No. 2003-147049 describes a wiring substrate. The entire contents of this publication are incorporated herein by reference.

### SUMMARY OF THE INVENTION

According to one aspect of the present invention, a component built-in wiring board includes a core substrate having an opening part, a connecting component positioned in the opening part of the core substrate and including electronic components, a first build-up part formed on a first surface side of the core substrate such that the first build-up part is covering the opening part of the core substrate on the first surface side of the core substrate, a second build-up part formed on a second surface side of the core substrate on the opposite side with respect to the first side such that the second build-up part is covering the opening part of the core substrate on the second surface side of the core substrate, and a filling resin part formed in the opening part of the core substrate such that the filling resin part is filling a space formed between the core substrate and the connecting component in the opening part of the core substrate. The connecting component includes a molding resin part positioning the electronic components spaced apart from each other therein, and penetrating conductors formed in the molding resin part, and the electronic components in the connecting component include a first component having terminals on the first surface side of the core substrate and a second component having terminals on the second surface side of the core substrate such that the penetrating conductors are formed on the second surface side of the core substrate and connected to the terminals of the second component on the second surface side of the core substrate.

According to another aspect of the present invention, a method for manufacturing a component built-in wiring board includes preparing a connecting component including electronic components including a first component and a second component, forming an opening part in a core substrate extending from a first surface of the core substrate to a second surface of the core substrate on the opposite side with respect to the first surface of the core substrate, inserting the connecting component into the opening part of the core substrate such that the first component has terminals on a first surface side of the core substrate and the second component has terminals on a second surface side of the core substrate, forming a filling resin part in the opening part of the core substrate such that the filling resin part fills a space formed between the core substrate and the connecting component in the opening part of the core substrate, laminating a first build-up part on the first surface side of the core substrate such that the first build-up part covers the opening part of the core substrate on the first surface side of the core substrate, and laminating a second build-up part on the second surface side of the core substrate on the opposite side with respect to the first side such that the second build-up part covers the opening part of the core substrate on the second surface side of the core substrate. The preparing the connecting component includes forming a molding resin part positioning the electronic components spaced apart from each other therein, and forming penetrating conductors in the molding resin part such that the penetrating conductors are formed on the second surface side of the core substrate and connected to the terminals of the second component on the second surface side of the core substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating a core substrate according to an embodiment of the present invention;

FIG. 2 is a cross-sectional view illustrating a state in which an opening part is formed in a core insulating layer of a core substrate according to an embodiment of the present invention;

FIG. 3 is a cross-sectional view illustrating a state in which an adhesive tape (T2) is attached to end faces of lands;

FIG. 4 is a cross-sectional view illustrating a state in which a connecting component, joined by a molding resin part, is inserted into the opening part a core substrate according to an embodiment of the present invention;

FIG. 5 is a cross-sectional view illustrating a state in which a filling resin constituting a filling resin part is filled in gaps between the opening part and the connecting component, and one interlayer insulating layer is laminated;

FIG. 6 is a cross-sectional view illustrating a core substrate according to an embodiment of the present invention in a state in which the adhesive tape attached to a first surface has been peeled off;

FIG. 7 is a cross-sectional view illustrating a state in which a core substrate according to an embodiment of the present invention with the adhesive tape peeled off in FIG. 6, has its up-down orientation inverted, and an interlayer insulating layer is laminated on the first surface side;

FIG. 8 is a cross-sectional view illustrating a state in which via holes are formed in the interlayer insulating layers;

FIG. 9 is a cross-sectional view illustrating a state in which lands and via conductors are formed in the interlayer insulating layers;

FIG. 10A is a cross-sectional view illustrating a state in which one surface of a base material of the connecting component is attached to an adhesive tape with an adhesive surface thereof facing upward;

FIG. 10B is a cross-sectional view illustrating a state in which multiple through holes of the same diameter are formed in the molding resin part on the other surface of the base material;

FIG. 10C is a cross-sectional view illustrating a state in which penetrating conductors and a surface layer are formed by plating the through holes and the other surface of the base material; and

FIG. 10D is a cross-sectional view illustrating a state in which the other surface in FIG. 10C has been polished.

### DETAILED DESCRIPTION OF THE EMBODIMENTS

Embodiments will now be described with reference to the accompanying drawings, wherein like reference numerals designate corresponding or identical elements throughout the various drawings.

### Overall Structure

FIG. 9 is a cross-sectional view illustrating a portion of a component built-in wiring board 10 according to an embodiment of the present invention (hereinafter, referred to as “the present embodiment”).

As illustrated in FIG. 9, the component built-in wiring board 10 of the present embodiment has multiple electronic components embedded within a laminated plate-like structure. The component built-in wiring board 10 includes a core substrate 20, a connecting component 70, a filling resin part 80, and build-up parts 60.

### Core Substrate

The core substrate 20 is a laminate, with one surface designated as a first surface (20A) and a surface on the opposite side designated as a second surface (20B). The core substrate 20 includes a core insulating layer 30, through-hole conductors 42, and lands (44, 46).

### Core Insulating Layer

The core insulating layer 30 is an insulator that forms a structural core of the core substrate 20. The core insulating layer 30 includes an insulating substrate 32, a reinforcing material 34, and resin layers 36. Specifically, the core insulating layer 30 is structured such that the resin layers 36 are respectively formed on both the first surface (20A) side and the second surface (20B) side of the insulating substrate 32, which contains the reinforcing material 34 internally. Further, in the core insulating layer 30, an opening part 50 is formed that penetrates from the first surface (20A) to the second surface (20B) through a height (H) of the core substrate 20. It is also possible that the insulating substrate 32 does not include the reinforcing material 34.

The resin layers 36 are each formed using a thermosetting resin sheet, for example, a prepreg. The resin layers 36 include a first resin layer (36A) formed on the first surface (20A) of the core substrate 20, and a second resin layer (36B) formed on the second surface (20B) of the core substrate 20.

### Through-Hole Conductors

The through-hole conductors 42 are each formed by forming a metal plating film such as copper plating on an inner wall of a through hole in the core insulating layer 30, filling an inner side of the metal plating film with a resin, and then applying cap plating to end surfaces thereof. The through-hole conductors 42 are each formed from the first surface (20A) to the second surface (20B) at a position different from that of the opening part 50.

### Lands

The lands (44, 46) are formed on surfaces of the resin layers 36 on opposite sides with respect to the core insulating layer 30. Specifically, the lands 44 are formed by plating on the first resin layer (36A) side, and the lands 46 are formed by plating on the second resin layer (36B) side. Some of the lands (44, 46) and the through-hole conductors 42 are electrically connected.

The core substrate 20 is structured as described above.

### Connecting Component

Next, the connecting component 70 is described.

The connecting component 70 is a component group in which multiple electronic components are joined by a molding resin part while being spaced apart from each other. The connecting component 70 is into inside the opening part 50.

The connecting component 70 includes a first component 72, a second component 74, a third component 76, a molding resin part 90, and penetrating conductors 92. The first component 72, the second component 74, and the third component 76 included in the connecting component 70 are, for example, passive components such as capacitors or inductors, or semiconductor elements.

### First Component

The first component 72 is box-shaped with a rectangular cross-section. The first component 72 has terminals on the first surface (20A) side. Further, no terminals are disposed on a top surface (72B) side of the first component 72, which is a surface on the opposite side with respect to a terminal surface (72A) of the terminals. That is, the first component 72 has terminals on only one surface. The terminal surface (72A) of the first component 72 is disposed on the first surface (20A) of the core substrate 20. A height from the terminal surface (72A) to the top surface (72B) is designated as a first height (H1). The first height (H1) is set to be lower than the height (thickness) (H) of the core substrate 20.

### Second Component

The second component 74 is box-shaped with a rectangular cross-section. The second component 74 is disposed away from the first component 72 in a direction perpendicular to a height direction of the first component 72.

The second component 74 has terminals on both end surfaces, on the first surface (20A) side and on the second surface (20B) side. A terminal surface (74A) of the second component 74 on the first surface (20A) side is disposed on the first surface (20A) of the core substrate 20. A terminal surface (74B) of the second component 74 on the second surface (20B) side is disposed closer to the first surface (20A) than to the second surface (20B). A height from the terminal surface (74A) to the terminal surface (74B) of the second component 74 is designated as a second height (H2). The second height (H2) is set to be lower than the height (thickness) (H) of the core substrate 20 and the first height (H1).

### Third Component

The third component 76 is box-shaped with a rectangular cross-section. The third component 76 is disposed away from the first component 72 on the opposite side with respect to the second component 74, such that the first component 72 is positioned between the second component 74 and the third component 76.

The third component 76 has terminals on both end surfaces, on the first surface (20A) side and on the second surface (20B) side. The third component 76 is an example of a first component that also has terminals on the second surface side. A terminal surface (76A) of the third component 76 on the first surface (20A) side is disposed on the first surface (20A) of the core substrate 20. A terminal surface (76B) on the second surface (20B) side is disposed closer to the first surface (20A) than to the second surface (20B). A height from the terminal surface (76A) to the terminal surface (76B) of the third component 76 is designated as a third height (H3). The third height (H3) is set to be lower than the height (thickness) (H) of the core substrate 20 and the first height (H1), and higher than the second height (H2).

### Molding Resin Part

The molding resin part 90 is a portion where the molding resin has solidified in a state including the first component 72, the second component 74, and the third component 76. The molding resin part 90 is an example of a second resin part. The molding resin part 90 fills the opening part 50 from the first surface (20A) to the second surface (20B) in a state in which the terminal surface (72A) of the first component 72, the terminal surface (74A) of the second component 74, and the terminal surface (76A) of the third component 76 are flush with each other.

### Penetrating Conductors

The penetrating conductors 92 are conductors formed by filling through holes 94 in the molding resin part 90 with plating. The penetrating conductors 92 are each formed extending from the terminal surface (74B) of the second component 74 or the terminal surface (76B) of the third component 76 toward the second surface (20B) of the core substrate 20, and each have an end surface along the second surface (20B). In other words, the penetrating conductors 92 are each formed to be connected to the terminal surface (74B) of the second component 74 or the terminal surface (76B) of the third component 76 in a state of penetrating the second surface (20B) side of the molding resin part 90. The “state of penetrating” of each of the penetrating conductors 92 refers to a state in which a predetermined space that opens at the second surface (20B) and reaches a terminal surface is filled. The formation of the penetrating conductors 92 will be described later.

The connecting component 70 is structured as described above.

### Filling Resin Part

Next, the filling resin part 80 is formed by solidifying a filling resin filled between the opening part 50 and the connecting component 70. The filling resin part 80 fills the opening part 50. The filling resin part 80 is an example of a first resin part. The filling resin of the filling resin part 80 is formed of, for example, an epoxy resin. Both end faces in a height (thickness) direction of the filling resin part 80 are respectively disposed on the first surface (20A) and second surface (20B) of the core substrate 20.

### Build-Up Parts

The build-up parts 60 are laminates disposed on the core substrate 20. The build-up parts 60 each include an interlayer insulating layer 62, lands 64, and via conductors 66. Further, the build-up parts 60 include a first build-up part (60A) and a second build-up part (60B). The first build-up part (60A) is formed on the first surface (20A) side of the core substrate 20. The second build-up part (60B) is formed on the second surface (20B) side of the core substrate 20. In other words, the first build-up part (60A) and the second build-up part (60B) are disposed so as to sandwich the core substrate 20 in a height (thickness) direction. In the present embodiment, for convenience of description, one interlayer insulating layer 62 is laminated in each of the first build-up part (60A) and the second build-up part (60B), but multiple layers may be laminated.

The interlayer insulating layer 62 is an insulating layer laminated in a direction away from the core substrate 20 from the first surface (20A) or the second surface (20B) of the core substrate 20. The interlayer insulating layer 62 is formed of the same resin as the filling resin part 80.

The lands 64 are conductor patterns formed on the interlayer insulating layer 62. The via conductors 66 are conductors formed by filling via holes 68 formed in the interlayer insulating layer 62 with plating. The via conductors 66 are electrically connected to the lands (44, 46, 64), the terminals of the connecting component 70, the penetrating conductors 92, and lands not illustrated.

### Formation of Penetrating Conductors

Next, a preparation process of a method for manufacturing the component built-in wiring board 10 of the present embodiment is described. Specifically, a process for preparing the connecting component 70 by forming the penetrating conductors 92 in a base material (M) of the connecting component 70 is described. In the present specification, the base material (M) is described as being structured as one unit containing one each of the first component 72, the second component 74, and the third component 76. However, the present invention is not limited to this. For example, the base material (M) may be structured with multiple units. In this case, the base material (M) is diced (singulated) at a predetermined time.

First, the base material (M) of the connecting component 70 is prepared. The base material (M) is covered with a molding resin part 90 in a state in which the terminal surface (72A) of the first component 72, the terminal surface (74A) of the second component 74, and the terminal surface (76A) of the third component 76 are flush with each other.

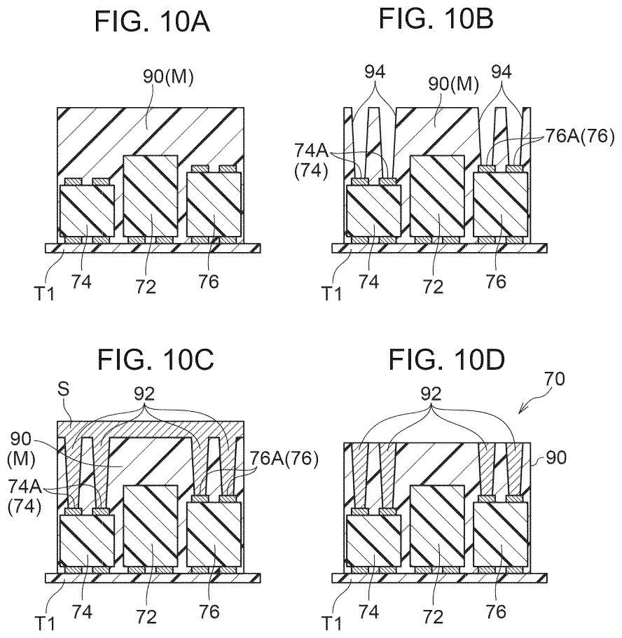

As illustrated in FIG. 10A, one surface of the base material (M) is attached to an adhesive tape (T1) with an adhesive surface of the adhesive tape (T1) facing upward. Next, as illustrated in FIG. 10B, the through holes 94 of the same diameter are formed in the molding resin part 90 on a surface on the opposite side with respect to the one surface of the base material (M) (hereinafter, this surface may be referred to as the other surface). The through holes 94 are formed to the terminal surface (74B) of the second component 74 or the terminal surface (76B) of the third component 76. The through holes 94 are formed, for example, with laser. However, the present invention is not limited to this.

Next, as illustrated in FIG. 10C, the penetrating conductors 92 and a surface layer(S) are formed by plating the through holes 94 and the other surface of the base material (M). For example, copper is used as a plating material for the plating.

Then, as illustrated in FIG. 10D, the other surface of the base material (M) is subjected to chemical mechanical polishing (CMP) to polish the surface layer(S) and a portion of the base material (M), thereby preparing the connecting component 70.

### Method for Manufacturing Component Built-In Wiring Board

Next, a method for manufacturing the component built-in wiring board 10 of the present embodiment is described.

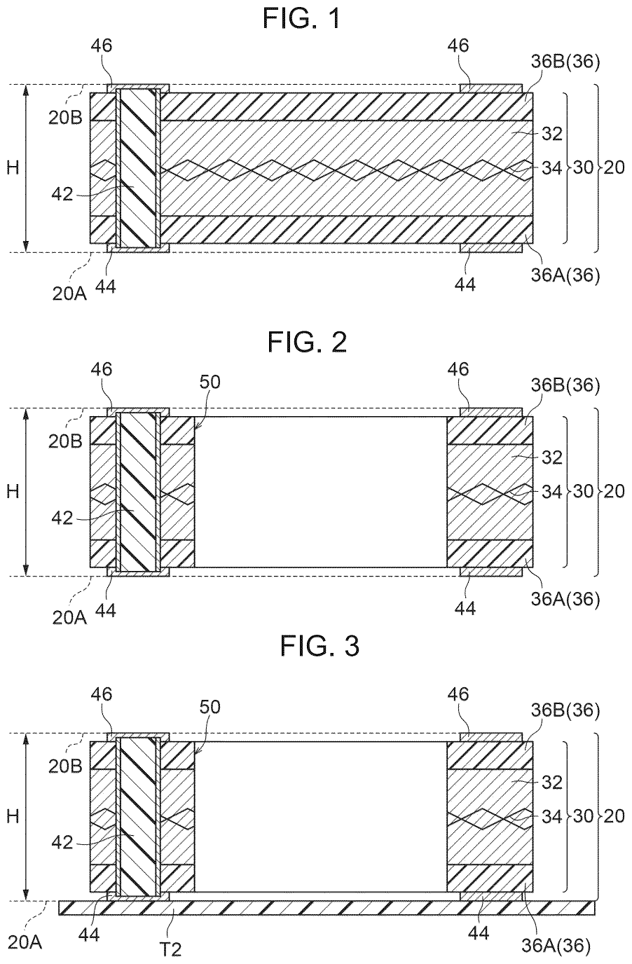

As illustrated in FIG. 1, the core substrate 20 is prepared.

As illustrated in FIG. 2, the opening part 50 is formed in the core insulating layer 30 of the core substrate 20.

As illustrated in FIG. 3, an adhesive tape (T2) is attached to end surfaces of the lands 44 of the core substrate 20 such that an adhesive surface of the adhesive tape (T2) faces the lands 44.

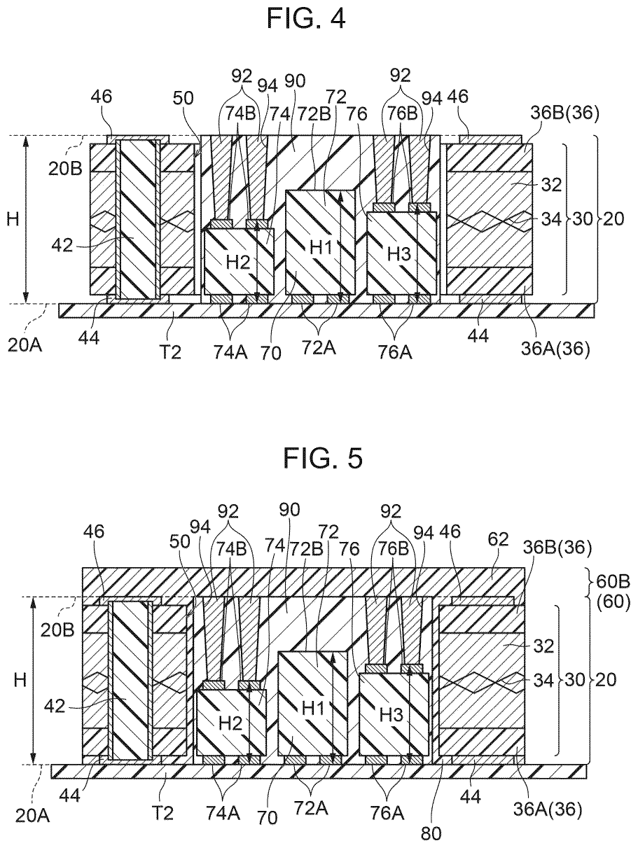

As illustrated in FIG. 4, the connecting component 70 is inserted into the opening part 50 from the terminal surface (72A) side, the terminal surface (74A) side, and the terminal surface (76A) side. During the insertion into the opening part 50, the connecting component 70 is attached to the adhesive surface of the adhesive tape (T2).

As illustrated in FIG. 5, a filling resin is filled in a gap between the opening part 50 and the connecting component 70. The filling resin solidifies to form the filling resin part 80, thereby fixing the connecting component 70 inside the opening part 50. In the present embodiment, after forming the filling resin part 80 above the second surface (20B) of the core substrate 20, a surface of the filling resin part 80 is polished (not illustrated). As a result of the polishing, one interlayer insulating layer 62 is laminated.

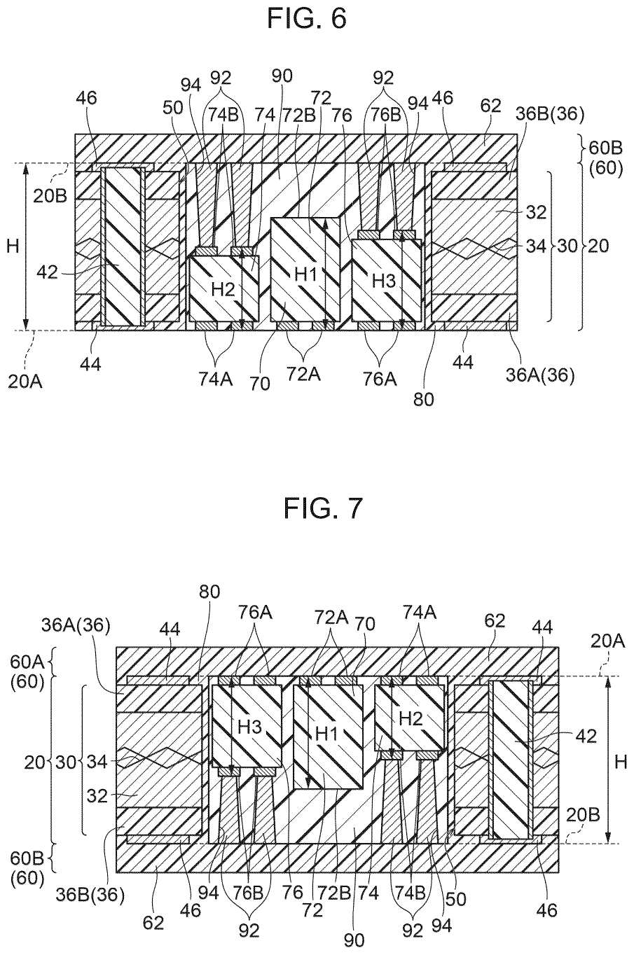

As illustrated in FIG. 6, the adhesive tape (T2) attached to the first surface (20A) side of the core substrate 20 is peeled off.

As illustrated in FIG. 7, the core substrate 20, from which the adhesive tape (T2) has been peeled off, is prepared with its up-down orientation inverted. FIG. 7 differs from FIGS. 1 to 5 in that the vertical positions of the first surface (20A) and the second surface (20B) are inverted. An interlayer insulating layer 62 is laminated on the first surface (20A) side of the core substrate 20, whose up-down orientation has been inverted, using the resin constituting the filling resin part 80.

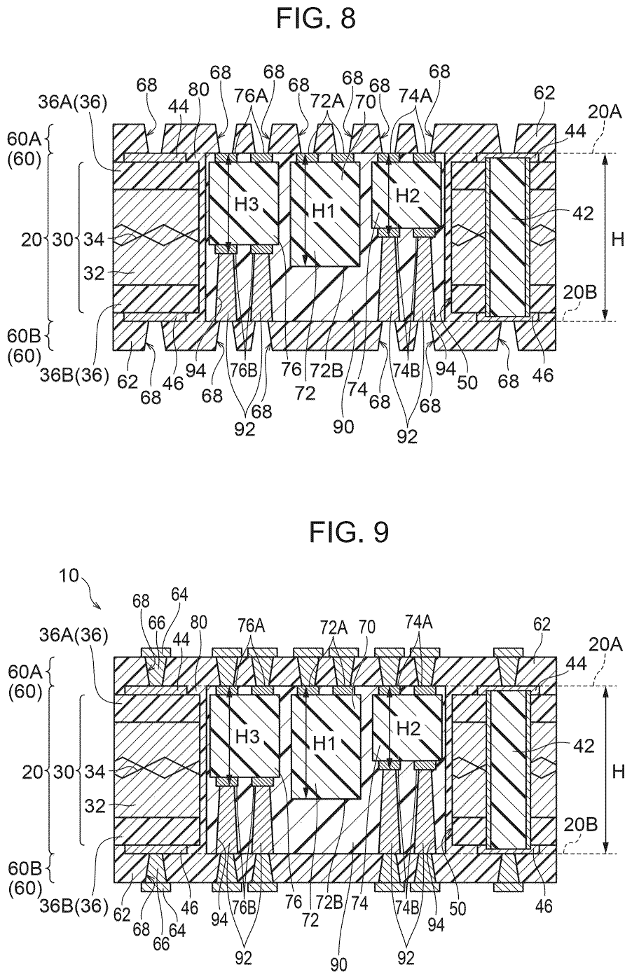

As illustrated in FIG. 8, the via holes 68 are formed in the interlayer insulating layers 62 on both sides of the core substrate 20 from a vertical direction. Specifically, the via holes 68 are formed toward the lands (44, 46), the terminal surfaces (72A, 74A, 76A), and the penetrating conductors 92.

Then, as illustrated in FIG. 9, the via conductors 66 are formed in the via holes 68, and the lands 64 are formed on the via conductors 66 and surroundings thereof, respectively.

Specifically, electroless plating is formed on the surfaces of the interlayer insulating layers 62 and on inner walls of the via holes 68. Next, a plating resist pattern is formed on the electroless plating. Further, electrolytic plating is formed in openings of the plating resist (not illustrated) on the surfaces of the interlayer insulating layers 62 and in the via holes 68. Then, the plating resist is peeled off. Finally, the electroless plating film is removed by etching. Thus, the lands 64 and the via conductors 66 are formed.

Depending on product specifications, multiple interlayer insulating layers 62 may be laminated.

Thus, the component built-in wiring board 10 is manufactured.

### Operational Effects

The component built-in wiring board 10 of the present embodiment includes: the core substrate 20 that has the first surface (20A) and the second surface (20B) and the opening part 50 penetrating from the first surface (20A) to the second surface (20B); the connecting component 70 that is inserted into the opening 50; the build-up parts 60 disposed on the core substrate 20; and the filling resin part 80 that fills the opening part 50. The connecting component 70 includes the first component 72 having terminals on the first surface (20A) side and the second component 74 having terminals on both the first surface (20A) side and the second surface (20B) side, which are joined by the molding resin part 90 such that the terminal surfaces (72A, 74A) on the first surface (20A) side are flush with each other. In the molding resin part 90, the penetrating conductors 92 are formed that penetrate the second surface (20B) side and are connected to the terminals of the second component 74 on the terminal surface (74B).

A method for manufacturing the component built-in wiring board 10 of the present embodiment includes: preparing the connecting component 70 that includes the first component 72 and the second component 74, the second component 72 having terminals on both surfaces; forming the opening part 50 that penetrates from the first surface (20A) of the core substrate 20 to the second surface (20B) on the opposite side; inserting the connecting component 70 into the opening part 50 from the terminal surface (72A, 74A) side of the electronic components; filling the opening part 50 with the filling resin part 80; and laminating the build-up parts 60 on the core substrate 20. The preparing of the connecting component 70 includes forming the penetrating conductors 92 in the molding resin part 90, which connects the first component 72 and the second component 74 such that the terminal surfaces (72A, 74A) on the first surface (20A) side of the first component 72 and the second component 74 are flush with each other, with the penetrating conductors 92 penetrating the second surface (20B) side and connected to the terminals of the second component 74 on the terminal surface (74B).

According to this structure, in a structure where the first component 72 and the second component 74, joined by the molding resin part 90, are inserted into the opening part 50 of the core substrate 20, since the penetrating conductors 92 are formed in the molding resin part 90, the second component 74 is connected via vias on both the first surface (20A) and the second surface (20B).

Further, in the component built-in wiring board 10 of the present embodiment, the penetrating conductors 92 are formed of a plating material filling the through holes 94 formed in the molding resin part 90.

According to this structure, compared to a structure where the penetrating conductors 92 are formed of a material different from the plating filling the through holes 94, the manufacturing of the component built-in wiring board is facilitated.

Further, in the component built-in wiring board 10 of the present embodiment, the via conductors 66 that connect to the terminals on the first surface (20A) side of the first component 72 and the second component 74 are formed in the first build-up part (60A) formed on the first surface (20A) side of the core substrate 20, and the via conductors 66 that connect to the penetrating conductors 92 are formed in the second build-up part (60B) formed on the second surface (20B) side of the core substrate 20.

According to this structure, the second component 74 is connected to the second build-up part (60B).

Further, in the component built-in wiring board 10 of the present embodiment, the first component 72 has the first height (H1), and the second component 74 has the second height (H2) lower than the first height (H1).

According to this structure, even a component with a low height can be connected via vias on both the first surface (20A) and the second surface (20B).

Further, the component built-in wiring board 10 of the present embodiment includes, in addition to the second component 74, the third component 76 having the terminal surfaces (76A, 76B) on both sides.

According to this structure, even when the electronic components have variations in height, all the components can be connected via vias on both the first surface (20A) and the second surface (20B).

Further, in the component built-in wiring board 10 and the manufacturing method therefor of the present embodiment, the molding resin part 90 fills the opening part 50 from the first surface (20A) to the second surface (20B).

According to this structure, compared to a structure where the opening part 50 is filled from the first surface (20A) to a position lower than the second surface (20B), the amount of resin constituting the filling resin part 80 can be reduced.

In the above, the present invention is described in detail with respect to specific embodiments. However, the present invention is not limited to these embodiments and that various other embodiments are possible within the scope of the present invention. For example, the following modified examples are possible. However, the present invention is not limited thereto.

### Modified Example

In the above embodiment, the penetrating conductors 92 of the component built-in wiring board 10 are formed of a plating material filling the through holes 94 formed in the molding resin part 90. However, the present invention is not limited to this. It is also possible that the penetrating conductors 92 are formed of a material different from the plating material filling the through holes 94.

In the above embodiment, the component built-in wiring board 10 is structured such that the first build-up part (60A) formed on the first surface (20A) side of the core substrate 20 has the via conductors 66 formed therein, connected to the terminals of the first component 72 and the second component 74, and the second build-up part (60B) formed on the second surface side of the core substrate 20 has the via conductors 66 formed therein, connected to the penetrating conductors 92. However, the present invention is not limited to this.

In the above embodiment, the component built-in wiring board 10 is structured such that the first component 72 has the first height (H1), and the second component 74 has the second height (H2) lower than the first height (H1). However, the present invention is not limited to this. It is also possible that the first height (H1) and the second height (H2) are the same or reversed.

In the component built-in wiring board 10 and the manufacturing method therefor of the above embodiment, the molding resin part 90 fills the opening part 50 from the first surface (20A) to the second surface (20B). However, the present invention is not limited to this. It is also possible that the molding resin part 90 fills the opening part 50 from the first surface (20A) to any height on the first surface (20A) side of the second surface (20B), or from any height on the second surface (20B) side of the first surface (20A) to the second surface (20B). In this case, the resin filling the gaps between the molding resin part 90 and the second surface (20B) or the first surface (20A) may be appropriately selected.

In the above embodiment, the second component 74 is structured to have terminals on both end surfaces on the first surface (20A) side and the second surface (20B) side. However, the present invention is not limited to this. For example, it is also possible that the second component 74 has terminals only on the end surface on the second surface (20B) side.

Japanese Patent Application Laid-Open Publication No. 2003-147049 describes a wiring substrate including a core substrate having an opening part, multiple electronic components disposed in the opening part with gaps therebetween in a state of being spaced apart from each other, and a build-up part disposed on the core substrate and on the electronic components, wherein the gaps are filled with resin.

In a structure where a first component and a second component, joined by a second resin part, are inserted into the opening part of the core substrate, it may be possible that the second component, which has terminals on a second surface, cannot be connected via vias at the second surface.

A component built-in wiring board according to an embodiment of the present invention includes: a core substrate that has a first surface, a second surface on the opposite side with respect to the first surface, and an opening part penetrating from the first surface to the second surface; multiple electronic components that are inserted into the opening part in a state of being space apart from each other; a build-up part that is disposed on the core substrate; and a first resin part that fills the opening part. The multiple electronic components include a first component having terminals on the first surface side and a second component having terminals on the second surface side, the first component and the second component being joined by a second resin part. Penetrating conductors are formed in the second resin part, that penetrate the second surface side and are connected to the terminals of the second component on the second surface side.

A method for manufacturing a component built-in wiring board according to another embodiment of the present invention includes: preparing multiple electronic components including a first component having terminals on a first surface side of a core substrate and a second component having terminals on a second surface side of the core substrate; preparing an opening part in the core substrate extending from the first surface to the second surface on the opposite side; inserting the multiple electronic components into the opening part in a state of being spaced apart from each other; filling the opening part with a first resin part; and laminating a build-up part on the core substrate. The preparing of the multiple electronic components includes forming penetrating conductors in a second resin part that connects the first component and the second component such that the penetrating conductors penetrate the second surface side and are connected to the terminals of the second component on the second surface side.

According to a component built-in wiring board and a method for manufacturing a component built-in wiring board according to embodiments of the present invention, in a structure where the first component and the second component, joined by the second resin part, are inserted into the opening part of the core substrate, since the penetrating conductors are formed in the second resin part, the second component can be connected via vias at the second surface.

Obviously, numerous modifications and variations of the present invention are possible in light of the above teachings. It is therefore to be understood that within the scope of the appended claims, the invention may be practiced otherwise than as specifically described herein.

1. A component built-in wiring board, comprising:
a core substrate having an opening part;
a connecting component positioned in the opening part of the core substrate and comprising a plurality of electronic components;
a first build-up part formed on a first surface side of the core substrate such that the first build-up part is covering the opening part of the core substrate on the first surface side of the core substrate;
a second build-up part formed on a second surface side of the core substrate on an opposite side with respect to the first side such that the second build-up part is covering the opening part of the core substrate on the second surface side of the core substrate; and
a filling resin part formed in the opening part of the core substrate such that the filling resin part is filling a space formed between the core substrate and the connecting component in the opening part of the core substrate,
wherein the connecting component includes a molding resin part positioning the electronic components spaced apart from each other therein, and a plurality of penetrating conductors formed in the molding resin part, and the plurality of electronic components in the connecting component includes a first component having terminals on the first surface side of the core substrate and a second component having terminals on the second surface side of the core substrate such that the penetrating conductors are formed on the second surface side of the core substrate and connected to the terminals of the second component on the second surface side of the core substrate.

2. The component built-in wiring board according to claim 1, wherein the second component of the electronic components in the connecting component has a plurality of terminals on the first surface side of the core substrate, and the first component and the second component are positioned in the molding resin part such that terminal surfaces of the first component and the second component on the first surface side are flush with each other.

3. The component built-in wiring board according to claim 1, wherein the plurality of penetrating conductors in the connecting component comprises a plating material filling holes formed in the molding resin part.

4. The component built-in wiring board according to claim 1, wherein the first build-up part includes a plurality of via conductors connected to the terminals of the first component on the first surface side of the core substrate, and the second build-up part includes a plurality of via conductors connected to the penetrating conductors of the connecting component on the second surface side of the core substrate.

5. The component built-in wiring board according to claim 1, wherein the first component of the electronic components in the connecting component has a first height, and the second component of the electronic components in the connecting component has a second height that is lower than the first height.

6. The component built-in wiring board according to claim 1, wherein the connecting component is formed such that the molding resin part is filling the opening part of the core substrate from a first surface of the core substrate to a second surface of the core substate on an opposite side with respect to the first surface of the core substrate.

7. The component built-in wiring board according to claim 2, wherein the plurality of penetrating conductors in the connecting component comprises a plating material filling holes formed in the molding resin part.

8. The component built-in wiring board according to claim 2, wherein the first build-up part includes a plurality of via conductors connected to the terminals of the first component on the first surface side of the core substrate, and the second build-up part includes a plurality of via conductors connected to the penetrating conductors of the connecting component on the second surface side of the core substrate.

9. The component built-in wiring board according to claim 2, wherein the first component of the electronic components in the connecting component has a first height, and the second component of the electronic components in the connecting component has a second height that is lower than the first height.

10. The component built-in wiring board according to claim 2, wherein the connecting component is formed such that the molding resin part is filling the opening part of the core substrate from a first surface of the core substrate to a second surface of the core substate on an opposite side with respect to the first surface of the core substrate.

11. The component built-in wiring board according to claim 3, wherein the first build-up part includes a plurality of via conductors connected to the terminals of the first component on the first surface side of the core substrate, and the second build-up part includes a plurality of via conductors connected to the penetrating conductors of the connecting component on the second surface side of the core substrate.

12. The component built-in wiring board according to claim 3, wherein the first component of the electronic components in the connecting component has a first height, and the second component of the electronic components in the connecting component has a second height that is lower than the first height.

13. The component built-in wiring board according to claim 3, wherein the connecting component is formed such that the molding resin part is filling the opening part of the core substrate from a first surface of the core substrate to a second surface of the core substate on an opposite side with respect to the first surface of the core substrate.

14. The component built-in wiring board according to claim 4, wherein the first component of the electronic components in the connecting component has a first height, and the second component of the electronic components in the connecting component has a second height that is lower than the first height.

15. The component built-in wiring board according to claim 4, wherein the connecting component is formed such that the molding resin part is filling the opening part of the core substrate from a first surface of the core substrate to a second surface of the core substate on an opposite side with respect to the first surface of the core substrate.

16. The component built-in wiring board according to claim 5, wherein the connecting component is formed such that the molding resin part is filling the opening part of the core substrate from a first surface of the core substrate to a second surface of the core substate on an opposite side with respect to the first surface of the core substrate.

17. A method for manufacturing a component built-in wiring board, comprising:
preparing a connecting component comprising a plurality of electronic components including a first component and a second component;
forming an opening part in a core substrate extending from a first surface of the core substrate to a second surface of the core substrate on an opposite side with respect to the first surface of the core substrate;
inserting the connecting component into the opening part of the core substrate such that the first component has terminals on a first surface side of the core substrate and the second component has terminals on a second surface side of the core substrate;
forming a filling resin part in the opening part of the core substrate such that the filling resin part fills a space formed between the core substrate and the connecting component in the opening part of the core substrate;
laminating a first build-up part on the first surface side of the core substrate such that the first build-up part covers the opening part of the core substrate on the first surface side of the core substrate; and
laminating a second build-up part on the second surface side of the core substrate on an opposite side with respect to the first side such that the second build-up part covers the opening part of the core substrate on the second surface side of the core substrate,
wherein the preparing the connecting component includes forming a molding resin part positioning the electronic components spaced apart from each other therein, and forming a plurality of penetrating conductors in the molding resin part such that the penetrating conductors are formed on the second surface side of the core substrate and connected to the terminals of the second component on the second surface side of the core substrate.

18. The method for manufacturing a component built-in wiring board according to claim 17, wherein the preparing the connecting component includes forming the molding resin part having the first component and the second component positioned therein such that the second component has terminals on the first surface side of the core substrate and that terminal surfaces of the terminals on the first surface side are flush with each other, and the inserting the connecting component comprise inserting the connecting component from a terminal surface side of the terminals on the first surface side of the core substrate.

19. The method for manufacturing a component built-in wiring board according to claim 17, wherein the forming of the filling resin part comprises filling resin material of the filling resin part into the opening part of the core substrate from the first surface of the core substrate to the second surface of the core substrate in the opening part of the core substrate.

20. The method for manufacturing a component built-in wiring board according to claim 18, wherein the forming of the filling resin part comprises filling resin material of the filling resin part into the opening part of the core substrate from the first surface of the core substrate to the second surface of the core substrate in the opening part of the core substrate.
